(19) United States
(12) Patent Application Publication
(10) Pub. No.: US 2009/0058531 A1
(43) Pub. Date: Mar. 5, 2009

(54) VARIABLE GAIN AMPLIFIER

(75) Inventors: Chien-Meen HWANG, San Jose, CA (US); David H. Shen, San Jose, CA (US); Ann P. Shen, Saratoga, CA (US)

Correspondence Address: FISH & RICHARDSON P.C., P.O. BOX 1022, MINNEAPOLIS, MN, 55440-1022, US

(73) Assignee: NanoAmp Solutions Inc. (CAYMAN), Santa Clara, CA (US)

(21) Appl. No.: 12/199,562

(22) Filed: Aug. 27, 2008

Related U.S. Application Data
(60) Provisional application No. 60/969,430, filed on Aug. 31, 2007.

(51) Int. Cl. H03G 3/00

(52) U.S. Cl. 330/278; 455/234.1

(57) ABSTRACT

Techniques and systems for receiving a signal at a first component with an adjustable gain, and adjusting the gain of the first component to a first gain value using a first gain step. Amplifying the signal with the first gain value, generating a first amplified signal, and receiving the first amplified signal at a second component with an adjustable gain. Adjusting a gain of the second component to a second gain value using a second gain step. The net gain step is smaller than one of the first or second gain step. Amplifying the first amplified signal with the second gain value to generate a second amplified signal, and receiving the second amplified signal at a filtering component. A transient response introduced by the filtering component on the second amplified signal is smaller than the transient response that would be introduced by the filtering component on the first amplified signal.

### CROSS REFERENCE TO RELATED APPLICATIONS

This application claims the benefit of priority from U.S. Provisional Application entitled “VARIABLE GAIN AMPLIFIER,” Application No. 60/969,430 filed Aug. 31, 2007, the disclosure of which is incorporated by reference.

### TECHNICAL FIELD

This disclosure relates to receivers and controlling the gain of received radio frequency (RF) communications signals in wireless and wireline applications.

### BACKGROUND

RF communications systems may amplify received signals with amplifiers that step up gain. Gain steps in gain blocks of an amplifier can introduce unwanted transient effects.

### SUMMARY

Generally, implementations may involve using an adjustable gain controller to adjust gain steps so as to minimize transient response in gain blocks. This can smooth out the transients of the gain control and enable better reception quality. The techniques described here can be compatible with digital algorithms used in communication systems and can provide for a radio receiver design with reduced transient responses to gain control changes, thereby improving receiver performance and decreasing error during gain changes.

According to one general aspect, a method comprising receiving a signal at a first component with an adjustable gain and adjusting the gain of the first component to a first gain value using a first gain step. The method also includes amplifying the signal with the first gain value to generate a first amplified signal and receiving the first amplified signal at a second component with an adjustable gain. The method further includes adjusting the gain of the second component to a second gain value using a second gain step such that the net gain step of the first and second gain steps is smaller than one of the first gain step or the second gain step. In addition, the method includes amplifying the first amplified signal with the second gain value to generate a second amplified signal and receiving the second amplified signal at a filtering component which introduces a transient response such that the transient response introduced by the filtering component on the second amplified signal is smaller than the transient response which would be introduced by the filtering component on the first amplified signal.

These and other implementations can optionally include one or more of the following features. For example, receiving the signal at the first component can include receiving the signal in a receiver operating to continuously receive and process radio frequency communication signals. Receiving the first amplified signal at the second component can include receiving the first amplified signal from an output terminal of the first component at an input terminal of the second component. Receiving the first amplified signal at the second component can include receiving the first amplified signal at the second component after the first amplified signal has been received and processed by one or more other components.

Also, receiving the first amplified signal at the second component can include receiving the first amplified signal from an output terminal of the first component at an input terminal of a mixer, mixing the first amplified signal, and receiving the first amplified signal as mixed from an output terminal of the mixer at an input terminal of the second component. Receiving the signal at the first component can include receiving the signal at a low noise amplifier. Receiving the signal at the first component can include receiving, at a mixer, a radio frequency signal that has been amplified with a low noise amplifier.

Further, adjusting the gain of the first component to the first gain value using the first gain step can include accessing stored gain tables, determining, from the accessed gain tables, the first gain step, and generating a first gain control signal configured to step up the gain of the first component to the first gain value with the first gain step. Adjusting the gain of the first component to the first gain value using the first gain step can include one of stepping up or stepping down the gain of the first component and adjusting the gain of the second component to the second gain value using the second gain step can include the other of stepping up or stepping down the gain of the second component. Adjusting the gain of the first component to the first gain value using the first gain step can include one of stepping up or stepping down the gain of the first component and adjusting the gain of the second component to the second gain value using the second gain step can include the other of stepping up or stepping down the gain of the second component such that the net gain step across the first component and the second component is in an order of 1 decibel.

Moreover, adjusting the gain of the second component to the second gain value using the second gain step can include adjusting the gain of the second component to multiple gain values in a sequence of gain values. The method can also include receiving the second amplified signal at a third component with an adjustable gain, adjusting the gain of the third component to a third gain value using a third gain step, wherein the net gain step of the first, second, and third gain steps is larger than the net gain step of the first and second gain steps, and amplifying the second amplified signal with the third gain value to generate a third amplified signal.

Adjusting the gain of the first component to the first gain value using the first gain step can include one of stepping up or stepping down the gain of the first component, adjusting the gain of the second component to the second gain value using the second gain step can include the other of stepping up or stepping down the gain of the second component, and adjusting the gain of the third component to the third gain value using the third gain step can include stepping up or stepping down the gain of the third component. The method can further include detecting a gain change instruction and adjusting the gain of the first component to the first gain value using the first gain step in response to the detected gain change instruction. The method can additionally include maintaining the gain of the first component at the first gain value and the gain of the second component at the second gain value until an additional gain change instruction is detected.

According to a second general aspect, a circuit comprises a receiver configured to receive a signal and a first component configured to amplify the received signal with an adjustable gain to create a first amplified signal. The circuit also includes a second component configured to amplify the first amplified signal with an adjustable gain to create a second amplified signal and a gain control circuit. The gain control circuit is configured to adjust the gain of the first component to a first gain value using a first control signal to create a first gain step and adjust the gain of the second component to a second gain value using a second control signal to create a second gain step such that the net gain step of the first and second gain steps is smaller than one of the first gain step or the second gain step. The circuit further includes a filtering component configured to filter the second amplified signal such that a transient response introduced by the filtering component on the second amplified signal is smaller than a transient response which would be introduced by the filtering component on the first amplified signal.

These and other implementations can optionally include one or more of the following features. For example, the gain control circuit can be an automatic gain controller including dedicated control circuits or a signal processor. The receiver can be configured to receive the signal while continuously operating to receive and process radio frequency communication signals. The second component can be configured to receive the first amplified signal from an output terminal of the first component at an input terminal of the second component. The second component can be configured to receive the first amplified signal at the second component after the first amplified signal has been received and processed by one or more other components.

Also, the one or more other components can include a mixer, the first component can be configured to output the first amplified signal at an output terminal of the first component to an input terminal of the mixer, and the second component can be configured to receive the first amplified signal at an input terminal of the second component as mixed from an output terminal of the mixer. The first component can be a low noise amplifier. The first component can be a mixer configured to receive a radio frequency signal that has been amplified with a low noise amplifier. To adjust the gain of the first component to the first gain value using the first control signal to create the first gain step, the gain control circuit can be configured to access stored gain tables, determine, from the accessed gain tables, the first gain step, and generate a first gain control signal configured to step up the gain of the first component to the first gain value with the first gain step.

Further, to adjust the gain of the first component to the first gain value using the first control signal to create the first gain step, the gain control circuit can be configured to create one of a step up or a step down of the gain of the first component, and to adjust the gain of the second component to the second gain value using the second control signal to create the second gain step, the gain control circuit can be configured to create the other of the step up or the step down of the gain of the second component. To adjust the gain of the first component to the first gain value using the first control signal to create the first gain step, the gain control circuit can be configured to create one of a step up or a step down of the gain of the first component, and to adjust the gain of the second component to the second gain value using the second control signal to create the second gain step, the gain control circuit can be configured to create the other of the step up or the step down of the gain of the second component such that the net gain step across the first component and the second component is approximately 1 decibel or less.

In additional, circuit can include a third component configured to amplify or attenuate the second amplified signal with an adjustable gain to create a third amplified signal, such that the gain control circuit is configured to adjust the gain of the third component to a third gain value using the third control signal to create a third gain step, where the net gain step of the first, second, and third gain steps is larger than the net gain step of the first and second gain steps. To adjust the gain of the first component to the first gain value using the first control signal to create the first gain step, the gain control circuit can be configured to create one of a step up or a step down of the gain of the first component, to adjust the gain of the second component to the second gain value using the second control signal to create the second gain step, the gain control circuit can be configured to create the other of the step up or the step down of the gain of the second component, and to adjust the gain of the third component to the third gain value using the third control signal to create the third gain step, the gain control circuit can be configured to create a step up of the gain of the third component.

Moreover, to adjust the gain of the third component to the third value using the third control signal to create the third gain step, the gain control circuit can be configured to adjust the gain of the third component using multiple gain steps in sequence of gain steps. To adjust the gain of the first component to a first gain value using the first control signal to create the first gain step, the gain control circuit can be configured to detect a gain change instruction and adjust the gain of the first component to the first gain value using the first control signal to create the first gain step in response to the detected gain change instruction. The gain control circuit can be configured to maintain the gain of the first component at the first gain value and the gain of the second component at the second gain value until an additional gain change instruction is detected.

According to a third general aspect, a system comprises an output terminal of an antenna coupled to an input terminal of a radio frequency filter (RF filter) and an output terminal of the RF filter coupled to an input terminal of a low noise amplifier (LNA). The system also includes an output terminal of the LNA coupled to a first input terminal of a mixer and an output terminal of the mixer coupled to an input terminal of a first amplifier. The system further includes an output terminal of the first amplifier coupled to an input terminal of a second filter. The gain controller includes at least one of a first control signal output terminal coupled to a control signal input terminal of the LNA or a second control signal output terminal coupled to a control signal input terminal of the mixer and a third control signal output terminal coupled to a control signal input terminal of the first amplifier. The gain controller is configured to generate control signals on the third and at least one of the first or second control signal output terminals such that the net gain step from the output terminal of the RF filter to the input terminal of the second filter is less than the net gain step from the output terminal of the RF filter to the output terminal of the mixer.

These and other implementations can optionally include one or more of the following features. For example, the gain controller can be configured to generate the first or second control signals to cause a step in gain of the LNA or the mixer and generate the third control signal to cause a step in gain of the first amplifier. The system can include an output terminal of the second filter coupled to an input terminal of a second amplifier such that the gain controller includes a fourth control signal output terminal coupled to a control signal input terminal of the second amplifier, and is configured to generate control signals on the third, fourth, and at least one of the first or second control signal output terminals such that the net gain step from the output terminal of the RF filter to the input terminal of the second filter is less than the net gain step from the output terminal of the RF filter to the output terminal of the mixer and is less than the net gain step from the output terminal of the RF filter to the output terminal of the second amplifier.

Also, the gain controller can be configured to generate the first or second control signals to cause a step in gain of the LNA or the mixer, generate the third control signal to cause a step in gain of the first amplifier, and generate the fourth control signal to cause a step in gain of the second amplifier. The gain controller can be configured to generate the first or second control signals to cause a step in gain of the LNA or the mixer, generate the third control signal to cause a step in gain of the first amplifier, and generate the fourth control signal to cause a gain ramp of two or more gain steps of the second amplifier.

In another general aspect, a method includes generating a first large gain step, in which the first large gain step includes a sequence of smaller gain steps, and receiving a signal at a component with an adjustable gain. The method involves adjusting the gain of the component to a sequence of gain values using the sequence of smaller gain steps, and amplifying the signal with the sequence of gain values to generate an amplified signal. The method includes receiving the amplified signal at a filtering component that introduces a transient response. The transient response introduced by the filtering component on the amplified signal is less than a transient response introduced by the filtering component on the first amplified signal if the gain of the component is adjusted to a second large gain step, in which the second large gain step is a single gain step (e.g., the second large gain step does not include a sequence of smaller gain steps). In some implementations, each transient response that is generated using each of the smaller gain steps is less than the transient response that would be generated if the second large gain step was used.

The details of one or more implementations are set forth in the accompanying drawings and the description below. Other features will be apparent from the description and drawings, and from the claims

### DESCRIPTION OF THE DRAWINGS

FIG. 1 is a schematic of an example of a receiver on an integrated chip.

FIG. 2A is a diagram of an example of a step change in gain value.

FIG. 2B is a diagram of an example of a transient response due to a gain step.

FIG. 3 is a schematic of an example of a receiver.

FIG. 4 is a block diagram of an example of a process using a compensation gain to reduce transient effects of a gain change.

FIG. 5A-5C are diagrams illustrating examples of waveforms that may be used to control a variable gain

FIG. 6 is a block diagram of an example of a process using a compensation gain and a supplemental gain to reduce transient effects of a gain change.

FIG. 7A-7C are diagrams illustrating examples of waveforms that may be used to control a variable gain using a supplemental gain.

FIG. 8 is a block diagram of an example of a process using multiple compensation gains.

FIG. 9A-9C are diagrams illustrating examples of waveforms that may be used to control a variable gain using multiple compensation gains

FIG. 10 is a schematic of an example of an RF receiver.

### DETAILED DESCRIPTION

With the growing demand for portable communications, it is desirable to design radio receivers that permit the integration of more components onto a single chip. Specifically, more of the analog front-end of the receiver chain may be integrated onto a chip.

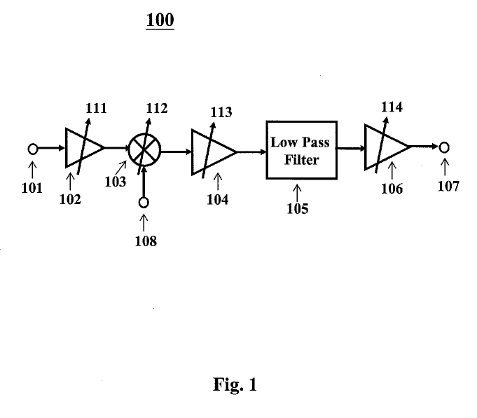

FIG. 1 is a diagram showing an example of a front-end receiver chain 100 that may be integrated on a chip.

The front-end chain 100 includes an RF signal at input 101, an LNA 102, a mixer 103 with local oscillator input 108, an amplifier 104, a low-pass filter 105, an additional amplifier 106, and an output 107. The output signal on output 107 is the result of amplified, filtered, and frequency converted processing of the input signal at the input 101. Each of the stages, including LNA 102, mixer 103, and amplifiers 104 and 106, can have control signals to set different gain values to accommodate a wide range of input signal powers. The control signal of the LNA 102 can be an analog or a digital control signal 111 and can produce LNA gain steps of multiple values.

The gain of a component “G” can be defined as a ratio of an input voltage to an output voltage. For example, the gain of a gain component can be a ratio of an output direct current (DC) voltage “V_{DCo} ” at an output terminal of the component to an input DC voltage “V_{DCi}” at an input terminal of the component. Also, the gain of a gain component can be defined to be a ratio of an input power at an input terminal of the component to an output power at an output terminal of the component. Many common LNA components usable as the LNA 102 adjust gain by stepping between only a few relatively large values, such as, for example, 6 and 20 dB.

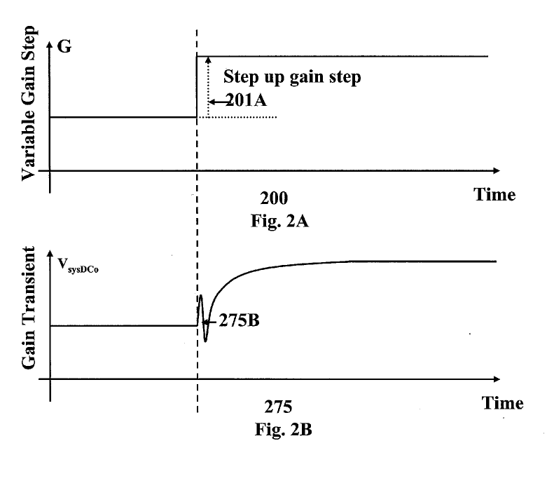

The mixer gain steps are typically steps of several values controlled by a second analog or digital control signal 112. Many common mixer components usable as the mixer 103, like the LNA components, adjust gain by stepping between only a few relatively large values, such as, for example, 6 and 20 dB. The amplifiers 104 and 106 can be variable gain amplification (VGA) stages with digital or analog control signals 113 and 114, respectively. The resolution of the amplification gain stages can be in the range of 1 dB to 6 dB steps, though other gain steps can be used. The total gain of the front-end 100 is the cascaded gain of all of the stages of the receiver chain. A component gain step can be referred to as a component gain change from a gain value to another gain value, and the difference of the two gains can be the size of the gain step. The term “gain step” as used in this disclosure may sometimes refer to a nearly instant change in gain as shown, for example, in FIG. 2A. Nevertheless, a gain step can also be implemented using continuous gain changes over a period of time or multiple discrete gain changes rather than a single nearly-instant gain change, such as a ramping gain step. In these implementations, a component itself can have fine gain step capabilities, and compensation may not be required if there is a ramp having a large gain step using smaller steps (e.g., a large gain step that is made up of smaller steps). In some of these implementations, instead of having a large gain change that generates a transient, the gain step can be ramped up and have negligibly small transients.

In many communications systems, the front-end gain steps of blocks such as the LNA 102 and mixer 103 can have large step sizes due to implementation considerations. These gain steps can be of the order of 6 dB to 15 dB. For example, FIG. 2A shows a diagram 200 of an example of a gain step for a low noise amplifier (LNA) 102 or mixer 103 in the receiver 100 of FIG. 1. The gain “G” of FIG. 2A can be the gain of a component in a system, for example, the LNA 102 or of the mixer 103 shown in FIG. 1. Diagram 200 shows a step up gain step of a gain size 201. The voltage V_{sysDCo} of FIG. 2B can be an output DC voltage at an output terminal of a system, for example, the receiver shown in FIG. 1.

FIG. 2B shows a diagram 275 of an example of a DC voltage component V_{sysDCo} at the output 107 including a transient response 275B generated from the low-pass filter 105 in response to the gain step shown in FIG. 2A. The transient response of a filter typically would show an exponential response that is proportional to the size of the gain step with a settling time constant related to the bandwidth of the filtering stage of the low-pass filter 105 inside the receiver 100. If the gain step is large enough, an unwanted transient may occur, as shown in diagram 275.

As a consequence of the changing power of the input signal at the input 101, a gain step command may be needed to change the receiver gain. As noted above, the gain step of the component used (e.g., the LNA 102 or the mixer 103) may be large enough to create an unwanted transient on the output as shown in diagram 275. If a gain step command is given during the reception of valid data, the transient response can have a damaging effect on the input data. In many frequency division duplexing systems that are continuously running (such as Wideband Code Division Multiple Access), the gain step may occur at the same time that data is being received. Thus, the data can be damaged, reducing receiver performance in obtaining data as well as increasing error rates of obtained data.

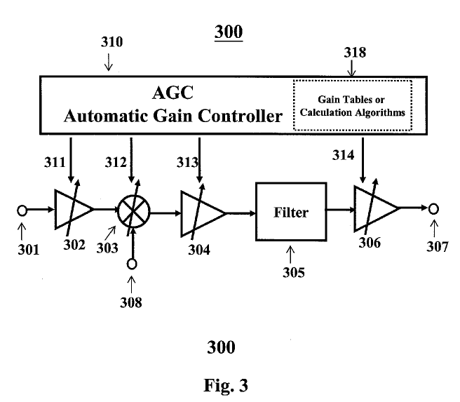

FIG. 3 shows a schematic of an example of an RF communications receiver 300 including an input 301 coupled to an input of an LNA 302. The output of the LNA 302 is coupled to the input of a mixer 303 to be mixed with a signal from a local oscillator 308. The output of the mixer couples to the input of the first variable gain amplifier (VGA) 304. The output of the first VGA 304 is coupled to the input of a filter 305. The filter 305 can be a low-pass filter. The output of the filter 305 is coupled to the input of a second VGA 306. The output of the second VGA 306 is an analog output 307.

The analog output 307 can be connected to an analog-to-digital converter to be demodulated in the digital domain or directly demodulated by analog circuits. A first control signal 311 is coupled to the gain control of the LNA 302. A second control signal 312 is coupled to the gain control of the mixer 303. A third control signal 313 is coupled to the gain control of the first VGA 304. A fourth control signal 314 is coupled to the gain control of the second VGA 306. An automatic gain controller (AGC) 310 can be a digital block that is used to control the control signals 311-314 to reduce the transient response from the filter 305 in response to a gain step at, for example, LNA 302 or mixer 303. The AGC 310 may include one or more gain tables or calculation algorithms 318 used in determining gain values or gain steps for components.

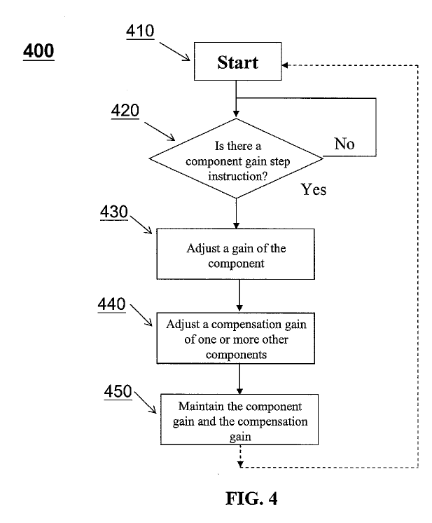

FIG. 4 shows a process 400 of using a compensation gain to reduce a filter transient effect from a filter, such as filter 305, due to a gain step in a component before the filter, such as LNA 302 or mixer 308. Specifically, the process 400 can reduce a filter transient response by adjusting a compensation gain to minimize a gain step and its resulting transient filter response. For ease of understanding, the process 400 is described in terms of the components of the schematic 300 of FIG. 3, though other components can be used.

The process 400 starts (410) and initially determines whether there is a component gain step instruction (420). For example, the AGC 310 can monitor for an instruction from a baseband directing a change of the gain of a system component, such as the mixer 303 or the LNA 302. In other implementations, the AGC can monitor component gain steps from algorithms or other system indicators. The process 400 can start (410) in a steady state from a previous component gain step (e.g., after the process ends with a maintained compensation gain 450).

Upon detecting the gain step instruction, the AGC 310 adjusts the gain of the component (430) using a gain step. In particular, the AGC 310 can use a control signal to adjust a component gain, such as, the first control signal 311 to adjust the LNA 302 and/or the second control signal 312 to adjust the mixer 303. In some implementations, the received gain step instruction itself indicates the gain step size. In other implementations, the AGC 310 determines the gain step size after receiving the gain step instruction. In particular, the AGC 310 can determine the gain step size or a desired gain value with which to determine the gain step size from a pre-determined gain table (e.g., values determined and stored prior to the start 410 of the process 400) or calculation algorithm 318 used to calculate the gain step size with an algorithm dynamically (e.g., determining the gain step size after the component gain change is detected 420).

The AGC 310 adjusts a compensation gain of one or more components other than the one that received the initial gain step (440) using another gain step. In particular, the AGC 310 can use a control signal to adjust a compensation gain, such as the third control signal 313 to adjust the first VGA 304. The compensation gain may be adjusted concurrent with or soon after the adjustment of the component gain. The size of the compensation gain used to achieve the compensation gain can be determined from the gain table or calculation algorithms 318. The combination of the adjusted component gain step (430) and the compensation gain step (440) can be used to reduce the transient response generated by the filter 305 in the output signal at the analog output 307.

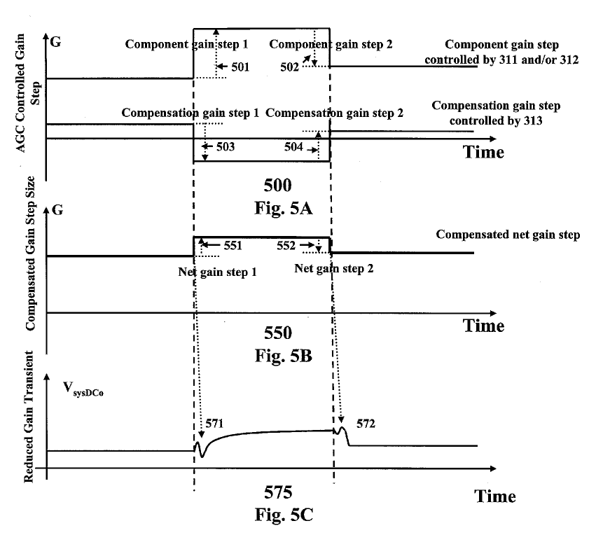

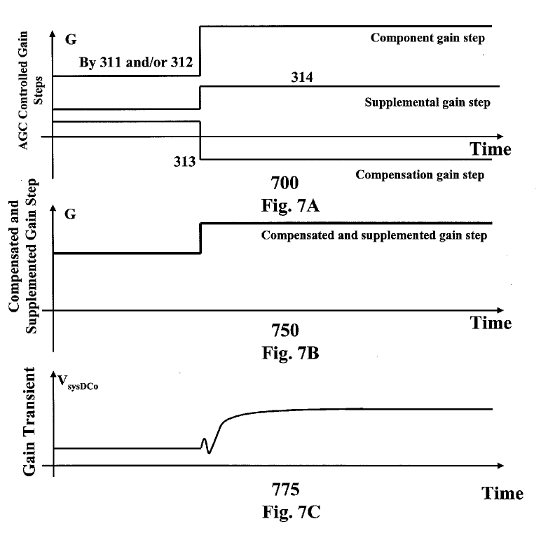

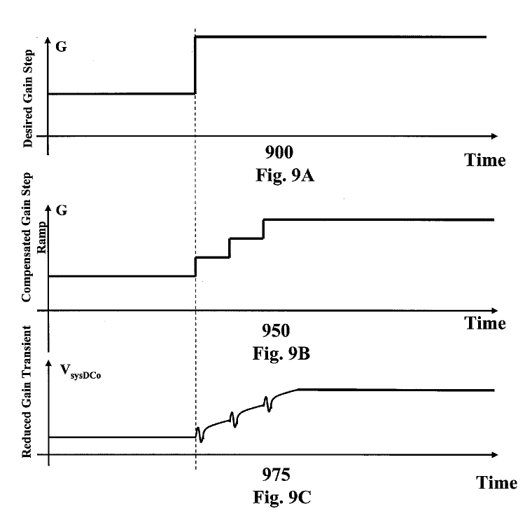

In various implementations, the adjustment of the gain of the component (430) and the adjustment of the compensation gain (440) occur concurrently or in the reverse order. The compensation gain can be a one step gain as shown in the diagrams of FIGS. 5A-5C and 7A-7C or a gain ramp with a series of gradual increasing small gain steps as shown in the diagrams of FIGS. 9A-9C. Thereafter, the AGC 310 maintains the component gain and the compensation gain (450). The AGC 310 can also monitor for a further component gain change.

FIGS. 5A-5C are diagrams of examples of how the variable gain can be controlled using the components of the schematic 300 of FIG. 3 and the process 400 of FIG. 4. Specifically, the diagram 500 of FIG. 5A illustrates an example of the gain step outputs controlled by the AGC 310 for two gain steps at two different times, the diagram 550 of FIG. 5B illustrates an example of two compensated gain steps which are the combination of the respective gain steps from the control signals 311 and/or 312 and the respective compensation gain steps, and the diagram 575 of FIG. 5C illustrates an example of a DC voltage component V_{sysDCo} of an output signal at the analog output 307.

The diagram 500 of FIG. 5A shows the gain steps controlled by the AGC 310 with the first and/or second control signals 311 and/or 312. The component gain step 1 of diagram 500 is a step up gain step of a size 501, and the component gain step 2 of diagram 500 is a step up gain step of a size 502. These control signals adjust the gain of a component (430) using a gain step and can be generated in response to receipt of a gain step instruction from the baseband (420). The frequency response of filter 305 can be the primary source of the unwanted transient response and can dictate the transient responses' characteristics in terms of shape and duration. For example, the bandwidth of the filter 305 can determine the settling time of the unwanted transient response. Therefore, without further compensation, a large step size of a gain in the LNA 302 and/or mixer 303 (e.g., 6 db to 20 db) created by the control signals 311 and/or 312 to an input signal to the filter 305 can cause a large transient response. However, the AGC 310 adjusts a compensation gain (440) using the third control signal 313, as shown by the diagram 500, to adjust the gain of the first VGA 304 using a gain step which offsets at least some of the gain step resulting from the control signals 311 and/or 312. Specifically, the compensation gain step 1 of diagram 500 is a step down gain step of a size 503 to compensate the step up component gain step 1 of the size 501, and the compensation gain step 2 of diagram 500 is a step up gain step of a size 504 to compensate the step down component gain step 2 of the size 502. The diagram 550 of FIG. 5B shows a resulting step up net compensated gain step 1 of size 551 and a resulting step down net compensated gain step 2 of size 552. The net gain step 1 size 551 and the net gain step 2 size 552 are smaller than the component gain step size 501 and the component gain step size 502, respectively. Thus, by ensuring a smaller net gain step in the signal input to filter 305, the transient response can be minimized.

In various implementations, the first VGA 304 has a gain step resolution of around 1 dB. Also, the first VGA 304 can exhibit a range sufficient to cover a combination of the LNA 302 and mixer 303 to minimize gain steps in the signal input to the filter 305. The diagram 550 of FIG. 5B illustrates a compensated gain step applied to the signal input to the filter 305. The diagram 575 of FIG. 5C illustrates a DC voltage transient response 571 and 572 of an output signal at the analog output 307 due to the compensated gain step shown in the diagram 550. Notably, as the gain step of the LNA 302 and/or the mixer 303 has been offset by the gain of the first VGA 304, the resulting gain step size shown in diagram 550 is small enough to produce the manageable transient of the output signal at the analog output 307 is illustrated in the diagram 575.

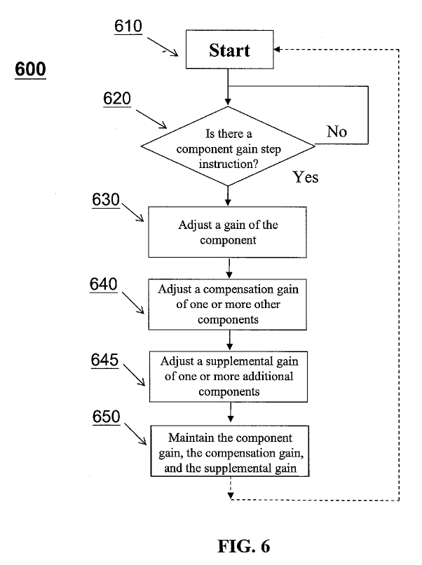

The net gain at the analog output 307, however, may be reduced to only a step size of about 1 dB. To achieve a larger net gain, an additional supplemental gain may be used. FIG. 6 shows a process 600 using compensation gain and supplemental gain. Specifically, the process 600 can reduce a transient response by adjusting a compensation gain using a gain step to minimize a gain step and its resulting transient response while maintaining a significant net gain of the system with a supplemental gain. The process 600 is similar to the process 400 except that process 600 includes the use of the supplemental gain. For ease of understanding, the process 600 is described in terms of the components of the schematic 300 of FIG. 3, though other components can be used.

The process 600 starts (610) and initially determines at the AGC 310 whether there is a component gain step instruction (620). Upon detecting the gain step instruction, the AGC 310 adjusts the gain of the component (630) using, for example, the first control signal 311 to adjust the LNA 302 gain with a gain step and/or the second control signal 312 to adjust the mixer 303 gain with a gain step. The AGC 310 adjusts a compensation gain of one or more other components (640) using, for example, the third control signal 313 to adjust the first VGA 304 gain with a gain step. The combination of the adjusted component gain step (630) and the compensation gain step (640) can be used to reduce the transient response generated by the filter 304 within an output signal at the analog output 307.

Without further gain, the net gain from the LNA 302 and/or mixer 303 as offset by the first VGA 304 may be a relatively low net gain (e.g., 1 db or less). To increase the net gain, the AGC 310 can adjust a supplemental gain of one or more additional components (645) using a gain step. The supplemental gain may be generated through a control signal from the AGC 310 to an additional component. For example, the AGC 310 may use the fourth control signal 314 to adjust the second VGA 306 to include a gain step of a larger gain than the first VGA 304. Thereafter, the AGC 310 maintains the component gain, the compensation gain, and the supplemental gain (650). The AGC 310 can also monitor for a further component gain change or instruction thereof.

FIGS. 7A-7C are diagrams of examples of how the variable gain can be controlled using the components of the schematic 300 of FIG. 3 and the process 600 of FIG. 6. Specifically, the diagram 700 of FIG. 7A illustrates an example of the gain step outputs of the AGC 310, the diagram 750 of FIG. 7B illustrates an example of the compensated and supplemented gain step or the net gain step of the system shown in FIG. 3, and the diagram 775 of FIG. 7C illustrates an example of the DC voltage component V_{sysDCo} of an output signal at the analog output 307.

The diagram 700 of FIG. 7A shows gain step outputs controlled by the AGC 310 with the first and/or second control signal 311 and/or 312. These control signals adjust the component gain (630) with a gain step and can be generated in response to receipt of a gain step instruction from the baseband (620). The AGC 310 adjusts a compensation gain (640) using the third control signal 313, as shown by the diagram 700, to adjust the gain of the first VGA 304 with a gain step to a gain which offsets at least some of the gain step resulting from the control signals 311 and/or 312. This ensures a small net gain step input to filter 305 to minimize the transient response.

The net gain step from the LNA 302, the mixer 303, and the first VGA 304 may be smaller than desired. To increase the net gain step while keeping the transient response from the filter 305 minimized, an additional amplification or attenuation after the filter 305 can be used. Specifically, the AGC 310 can adjust a supplemental gain of one or more components (645) with a gain step. For example, the AGC 310 can use the fourth control signal 314 to adjust the second VGA 306 to exhibit a gain step occurring after the filter 305. In general, the transient step response resulting from the second VGA 306 can be independent of the filter 305 and can settle in a time-span based upon the settling response of the second VGA 306 rather than the filter 305.

The diagram 750 of FIG. 7B illustrates a net gain or compensated and supplemented gain step of the receiver 300 shown in FIG. 3. Notably, the gain step size of diagram 750 of FIG. 7B is larger then the gain step size of the diagram 550 of FIG. 5B due to the supplemental gain step. The diagram 775 of FIG. 7C illustrates a transient response to the gain step shown in the diagram 750 at the analog output 307. Notably, as the gain step of the LNA 302 and the mixer 303 has been offset by the gain step of the first VGA 304 and the gain step of the second VGA 306 occurs after the filter 305, the resulting transient of the DC voltage component V_{sysDCo} in an output signal at the analog output 307 as illustrated in the diagram 775 is reduced.

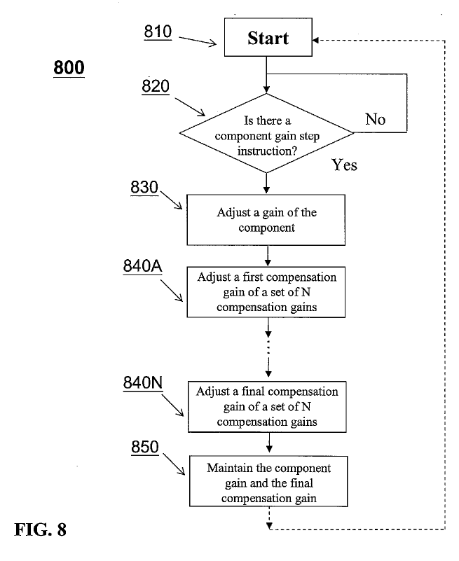

If a larger net gain step is desired, additional techniques may be used to achieve the gain while minimizing the transient response. For example multiple compensation gain steps may be used to step or ramp up the compensation gain step so as to achieve a larger net gain step without the transient response which a single gain jump to the larger gain would generate. FIG. 8 is a block diagram of an example of a process 800 using multiple compensation gains. For ease of understanding, the process 800 is described in terms of the components of the schematic 300 of FIG. 3, though other components can be used.

The process 800 starts (810) and initially determines at the AGC 310 whether there is a component gain change instruction (820). Upon detecting the gain step instruction, the AGC 310 adjusts the gain of the component (830) using, for example, the first control signal 311 to adjust the LNA 302 gain with a gain step and/or the second control signal 312 to adjust the mixer 303 gain with a gain step. The AGC 310 adjusts a compensation gain in a ramping fashion using another component to create N smaller compensation gain steps (840A-840N) with N compensation gain steps. For example, the AGC 310 can use the third control signal 313 to adjust the compensation gain in N smaller compensation gain steps.

The sizes of the compensation gain steps of the set of compensation gain steps can be determined by the AGC 310 from the gain tables or calculation algorithms 318 of the AGC 310. The set of compensation gains can include two or more gains (i.e. “N” is 2 or greater). The gain step of each compensation gain of the set of compensation gains is configured to increase the net gain step without adding a significant transient response. Therefore, each gain step can be a relatively small step from the proceeding gain. (e.g., 1 db). Next, the AGC 310 maintains the component gain and the final compensation gain (850). The AGC 310 can also monitor for a further component gain step instruction.

FIGS. 9A-9C are diagrams of examples of how the variable gain can be controlled using the components of the schematic 300 of FIG. 3 and the process 800 of FIG. 8. Specifically, the diagram 900 of FIG. 9A illustrates an example of a desired gain step, the diagram 950 of FIG. 9B illustrates an example of a compensated gain ramp of the first VGA 304, and the diagram 975 of FIG. 9C illustrates an example of the DC voltage component V_{sysDCo} of an output signal at the analog output 307. In some implementations, the desired system gain step can be achieved without the second VGA 306.

The diagram 900 of FIG. 9A illustrates a desired gain step, such as the gain step by the LNA 302 and/or mixer 303. Generating such a gain step with the LNA 302 and/or mixer 303 can introduce undesired transient effects to the output signal at the analog output 307. Therefore, a ramping compensation gain of multiple smaller compensation gain steps can be generated using the third control signals 313 to control the VGA 304 as shown for FIGS. 5A and 7A (not shown in FIG. 9A). These control signals adjust the compensation gains of a component (840A-840N) using compensation gain steps and can be generated in response to receipt of a gain step instruction from the baseband (820).

In order to achieve the larger desired gain step, the AGC 310 can generate a ramp of compensation gain step through a series of smaller gain steps. In particular, the AGC 310 can adjust each of a first through a final compensation gain of a set of N compensation gains (840A-840N) using, for example, the third control signal 313 to adjust the first VGA 304 gain with multiple compensation gains. The diagram 950 of FIG. 9B illustrates an exemplary net compensated gain step ramp created by the AGC 310. In one implementation, the gain step ramp includes three steps as shown in the diagram 950 and each step is of 2 dB for a total gain step of 6 dB after the third step. Other implementations may include differing numbers of steps and/or gain sizes in each step.

The diagram 975 of FIG. 9C illustrates a DC transient response from the filter 305 in an output signal at the analog output 307 to the gain step ramp shown in the diagram 950. Notably, as the gain of the LNA 302 and the mixer 303 has been sequentially augmented by the multiple gain steps of the first VGA 304, the resulting gain ramp shown in diagram 950 includes gain steps small enough to produce the manageable transient of the output signal at the analog output 307 as illustrated in the diagram 975.

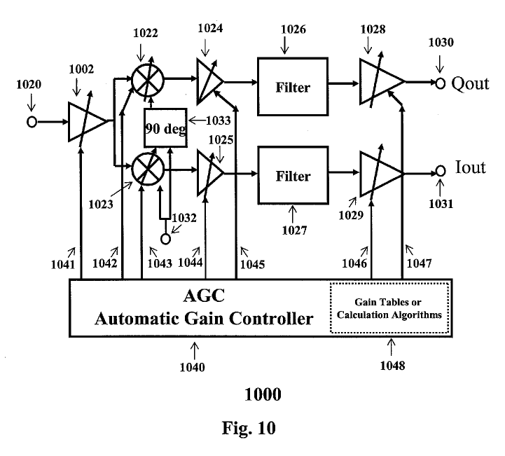

FIG. 10 is a schematic of an example of an RF receiver 1000. The receiver 1000 includes an RF signal input 1020 coupled to an input of an LNA 1002. An output of the LNA 1002 is coupled to an input of the quadrature mixer 1022 and an in-phase mixer 1023. A local oscillator 1032 drives an input of the in-phase mixer 1023 and creates a quadrature local oscillator signal through a phase-shifter 1033 to drive an input of the quadrature mixer 1022.

An output of the quadrature mixer 1022 is coupled to an input of a first quadrature VGA 1024. An output of the in-phase mixer 1023 is coupled to an input of a first in-phase VGA 1025. An output of the first quadrature VGA 1024 is coupled to an input of a quadrature filter 1026, such as a low-pass filter. An output of the first in-phase VGA 1025 is coupled to an input of an in-phase filter 1027, such as a low-pass filter. An output of the quadrature filter 1026 is coupled to an input of a second quadrature VGA 1028. An output of the in-phase filter 1027 couples to an input of a second in-phase VGA 1029. An output of the second quadrature VGA 1028 is coupled to a quadrature analog output 1030. An output of the second in-phase VGA 1029 is coupled to an in-phase analog output 1031. The quadrature and in-phase analog outputs 1030 and 1031 can be connected to an analog-to-digital converter to be demodulated in the digital domain or directly demodulated by analog circuits.

An AGC 1040 can be a digital or analog block that used to control the analog or digital control signals 1041-1047 so as to minimize the transient response of the receiver in response to a gain step as described above with respect to the processes 400, 600, and 800. The AGC 1040 may include one or more gain tables or calculation algorithms 1048 used in determining gain values or gain step sizes in gain changes for components. Control signal 1041 is coupled to a gain control of the LNA 1002. Control signal 1042 is coupled to a gain control of the quadrature mixer 1022. Control signal 1043 is coupled to a gain control of the in-phase mixer 1023. Control signal 1044 is coupled to a gain control of the first in-phase VGA 1025. Control signal 1045 is coupled to a gain control of the first quadrature VGA 1024. Control signal 1046 is coupled to a gain control of the second in-phase VGA 1029. Control signal 1047 is coupled to a gain control of the second quadrature VGA 1028. The number and order of variable gain and filter stages can vary. In addition the number of controllable steps, as well as the steps sizes of each of the stages of gain can also vary.

The system can include other components. Some of the components can include computers, processors, clocks, radios, signal generators, counters, test and measurement equipment, function generators, oscilloscopes, phase-locked loops, frequency synthesizers, phones, wireless communication devices, and components for the production and transmission of audio, video, and other data. The number and order of amplifiers and filter stages can vary

For example, while the implementations presented herein use single-ended structures, differential structures can be used in their place with the added advantages of improved symmetry and more robustness to noise. In addition, various types of data converters for analog-to-digital and digital-to-analog conversions, including delta-sigma modulators of various orders, various numbers of output bits, various structures, and various implementations can be used. Other types of data converters could include successive approximation, oversampling, or noise shaping data converters. Various types of analog or digital gain control methods can be used. Various kinds of digital multipliers can be used and various bit resolutions for the digital multiplier can be used. Various methods for calibrating the compensation table can be used. The circuits can be implemented in various integrated circuit technologies, such as CMOS, SiGe, and GaAs. Additional and/or different features may be encompassed by the following.

What is claimed is:

1. A method comprising:
receiving a signal at a first component with an adjustable gain;
adjusting the gain of the first component to a first gain value using a first gain step;
amplifying the signal with the first gain value to generate a first amplified signal;
receiving the first amplified signal at a second component with an adjustable gain;
adjusting the gain of the second component to a second gain value using a second gain step, wherein the net gain step of the first and second gain steps is smaller than one of the first gain step or the second gain step;
amplifying the first amplified signal with the second gain value to generate a second amplified signal; and
receiving the second amplified signal at a filtering component which introduces a transient response, wherein the transient response introduced by the filtering component on the second amplified signal is smaller than the transient response which would be introduced by the filtering component on the first amplified signal.

2. The method of claim 1 wherein receiving the signal at the first component includes receiving the signal in a receiver operating to continuously receive and process radio frequency communication signals.

3. The method of claim 1 wherein receiving the first amplified signal at the second component includes receiving the first amplified signal from an output terminal of the first component at an input terminal of the second component.

4. The method of claim 1 wherein receiving the first amplified signal at the second component includes receiving the first amplified signal at the second component after the first amplified signal has been received and processed by one or more other components.

5. The method of claim 4 wherein receiving the first amplified signal at the second component includes:
receiving the first amplified signal from an output terminal of the first component at an input terminal of a mixer;
mixing the first amplified signal; and
receiving the first amplified signal as mixed from an output terminal of the mixer at an input terminal of the second component.

6. The method of claim 1 wherein receiving the signal at the first component includes receiving the signal at a low noise amplifier.

7. The method of claim 1 wherein receiving the signal at the first component includes receiving, at a mixer, a radio frequency signal that has been amplified with a low noise amplifier.

8. The method of claim 1 wherein adjusting the gain of the first component to the first gain value using the first gain step includes:
accessing stored gain tables;
determining, from the accessed gain tables, the first gain step; and
generating a first gain control signal configured to step up the gain of the first component to the first gain value with the first gain step.

9. The method of claim 1 wherein:
adjusting the gain of the first component to the first gain value using the first gain step includes one of stepping up or stepping down the gain of the first component; and
adjusting the gain of the second component to the second gain value using the second gain step includes the other of stepping up or stepping down the gain of the second component.

10. The method of claim 1 wherein:
adjusting the gain of the first component to the first gain value using the first gain step includes one of stepping up or stepping down the gain of the first component; and
adjusting the gain of the second component to the second gain value using the second gain step includes the other of stepping up or stepping down the gain of the second component, wherein the net gain step across the first component and the second component is in an order of 1 decibel.

11. The method of claim 1 wherein adjusting the gain of the second component to the second gain value using the second gain step includes adjusting the gain of the second component to multiple gain values in a sequence of gain values.

12. The method of claim 1 further comprising:
receiving the second amplified signal at a third component with an adjustable gain;
adjusting the gain of the third component to a third gain value using a third gain step, wherein the net gain step of the first, second, and third gain steps is larger than the net gain step of the first and second gain steps; and
amplifying the second amplified signal with the third gain value to generate a third amplified signal.

13. The method of claim 12 wherein:
adjusting the gain of the first component to the first gain value using the first gain step includes one of stepping up or stepping down the gain of the first component;
adjusting the gain of the second component to the second gain value using the second gain step includes the other of stepping up or stepping down the gain of the second component; and
adjusting the gain of the third component to the third gain value using the third gain step includes stepping up or stepping down the gain of the third component.

14. The method of claim 1 further comprising:
detecting a gain change instruction; and
adjusting the gain of the first component to the first gain value using the first gain step in response to the detected gain change instruction.

15. The method of claim 14 further comprising maintaining the gain of the first component at the first gain value and the gain of the second component at the second gain value until an additional gain change instruction is detected.

16. A circuit comprising:
a receiver configured to receive a signal;
a first component configured to amplify the received signal with an adjustable gain to create a first amplified signal;
a second component configured to amplify the first amplified signal with an adjustable gain to create a second amplified signal;
a gain control circuit configured to:
adjust the gain of the first component to a first gain value using a first control signal to create a first gain step, and
adjust the gain of the second component to a second gain value using a second control signal to create a second gain step, wherein the net gain step of the first and second gain steps is smaller than the first gain step; and
a filtering component configured to filter the second amplified signal, wherein a transient response introduced by the filtering component on the second amplified signal is smaller than a transient response which would be introduced by the filtering component on the first amplified signal.

17. The circuit of claim 16 wherein the gain control circuit is an automatic gain controller including dedicated control circuits or a signal processor.

18. The circuit of claim 16 wherein the receiver is configured to receive the signal while continuously operating to receive and process radio frequency communication signals.

19. The circuit of claim 16 wherein the second component is configured to receive the first amplified signal from an output terminal of the first component at an input terminal of the second component.

20. The circuit of claim 16 wherein the second component is configured to receive the first amplified signal at the second component after the first amplified signal has been received and processed by one or more other components.

21. The circuit of claim 20 wherein:
the one or more other components include a mixer;
the first component is configured to output the first amplified signal at an output terminal of the first component to an input terminal of the mixer; and
the second component is configured to receive the first amplified signal at an input terminal of the second component as mixed from an output terminal of the mixer.

22. The circuit of claim 16 wherein the first component is a low noise amplifier.

23. The circuit of claim 16 wherein the first component is a mixer configured to receive a radio frequency signal that has been amplified with a low noise amplifier.

24. The circuit of claim 16 wherein, to adjust the gain of the first component to the first gain value using the first control signal to create the first gain step, the gain control circuit is configured to:
access stored gain tables;
determine, from the accessed gain tables, the first gain step; and
generate a first gain control signal configured to step up the gain of the first component to the first gain value with the first gain step.

25. The circuit of claim 16 wherein:
to adjust the gain of the first component to the first gain value using the first control signal to create the first gain step, the gain control circuit is configured to create one of a step up or a step down of the gain of the first component; and
to adjust the gain of the second component to the second gain value using the second control signal to create the second gain step, the gain control circuit is configured to create the other of the step up or the step down of the gain of the second component.

26. The circuit of claim 16 wherein:
to adjust the gain of the first component to the first gain value using the first control signal to create the first gain step, the gain control circuit is configured to create one of a step up or a step down of the gain of the first component; and
to adjust the gain of the second component to the second gain value using the second control signal to create the second gain step, the gain control circuit is configured to create the other of the step up or the step down of the gain of the second component, wherein the net gain step across the first component and the second component is approximately 1 decibel or less.

27. The circuit of claim 16 further comprising:
a third component configured to amplify or attenuate the second amplified signal with an adjustable gain to create a third amplified signal,
wherein the gain control circuit is configured to adjust the gain of the third component to a third gain value using the third control signal to create a third gain step, wherein the net gain step of the first, second, and third gain steps is larger than the net gain step of the first and second gain steps.

28. The circuit of claim 27 wherein:
to adjust the gain of the first component to the first gain value using the first control signal to create the first gain step, the gain control circuit is configured to create one of a step up or a step down of the gain of the first component;
to adjust the gain of the second component to the second gain value using the second control signal to create the second gain step, the gain control circuit is configured to create the other of the step up or the step down of the gain of the second component; and
to adjust the gain of the third component to the third gain value using the third control signal to create the third gain step, the gain control circuit is configured to create a step up of the gain of the third component.

29. The circuit of claim 27 wherein to adjust the gain of the third component to the third gain value using the third control signal to create the third gain step, the gain control circuit is configured to adjust the gain of the third component using multiple gain steps in sequence of gain steps.

30. The circuit of claim 16 wherein to adjust the gain of the first component to a first gain value using the first control signal to create the first gain step, the gain control circuit is configured to:
detect a gain change instruction; and
adjust the gain of the first component to the first gain value using the first control signal to create the first gain step in response to the detected gain change instruction.

31. The circuit of claim 30 wherein the gain control circuit is configured to maintain the gain of the first component at the first gain value and the gain of the second component at the second gain value until an additional gain change instruction is detected.

32. A system comprising:
an output terminal of an antenna coupled to an input terminal of a radio frequency filter (RF filter);
an output terminal of the RF filter coupled to an input terminal of a low noise amplifier (LNA);
an output terminal of the LNA coupled to a first input terminal of a mixer;
an output terminal of the mixer coupled to an input terminal of a first amplifier;
an output terminal of the first amplifier coupled to an input terminal of a second filter; and
a gain controller including:
at least one of a first control signal output terminal coupled to a control signal input terminal of the LNA or a second control signal output terminal coupled to a control signal input terminal of the mixer,
a third control signal output terminal coupled to a control signal input terminal of the first amplifier, and
wherein the gain controller is configured to generate control signals on the third and at least one of the first or second control signal output terminals such that the net gain step from the output terminal of the RF filter to the input terminal of the second filter is less than the net gain step from the output terminal of the RF filter to the output terminal of the mixer.

33. The system of claim 32 the gain controller is configured to:
generate the first or second control signals to cause a step in gain of the LNA or the mixer; and
generate the third control signal to cause a step in gain of the first amplifier.

34. The system of claim 32 further comprising an output terminal of the second filter coupled to an input terminal of a second amplifier wherein:
the gain controller includes a fourth control signal output terminal coupled to a control signal input terminal of the second amplifier,
wherein the gain controller is configured to generate control signals on the third, fourth, and at least one of the first or second control signal output terminals such that the net gain step from the output terminal of the RF filter to the input terminal of the second filter is less than the net gain step from the output terminal of the RF filter to the output terminal of the mixer and is less than the net gain step from the output terminal of the RF filter to the output terminal of the second amplifier.

35. The system of claim 34 the gain controller is configured to:
generate the first or second control signals to cause a step in gain of the LNA or the mixer;
generate the third control signal to cause a step in gain of the first amplifier; and
generate the fourth control signal to cause a step in gain of the second amplifier.

36. The system of claim 34 the gain controller is configured to:
generate the first or second control signals to cause a step in gain of the LNA or the mixer;
generate the third control signal to cause a step in gain of the first amplifier; and
generate the fourth control signal to cause a gain ramp of two or more gain steps of the second amplifier.

37. A method comprising:
generating a first large gain step, wherein the first large gain step comprises a sequence of smaller gain steps;
receiving a signal at a component with an adjustable gain;
adjusting the gain of the component to a sequence of gain values using the sequence of smaller gain steps;
amplifying the signal with the sequence of gain values to generate an amplified signal; and
receiving the amplified signal at a filtering component that introduces a transient response, wherein the transient response introduced by the filtering component on the amplified signal is less than a transient response introduced by the filtering component on the amplified signal if the gain of the component is adjusted to a second large gain step, wherein the second large gain step comprises a single gain step.
